(19) United States
(12) Patent Application Publication
(10) Pub. No.: US 2026/0114232 A1
(43) Pub. Date: Apr. 23, 2026

(54) WAFER TRANSFER TOOL

(71) Applicant: Taiwan Semiconductor Manufacturing Company Limited, Hsin-Chu (TW)

(72) Inventors: Chien-Cheng LIN, New Taipei City (TW); Jia-Wei TSENG, Hsinchu City (TW); Hung-Chih WANG, Taichung City (TW); Yuan-Hsin CHI, Taichung County (TW); Sheng-Yuan LIN, Hsinchu (TW)

(21) Appl. No.: 18/924,141

(22) Filed: Oct. 23, 2024

(51) Int. Cl. H01L 21/687; B65G 47/90

(52) U.S. Cl. CPC H10P 72/7602; B65G 47/90; B65G 2201/022

(57) ABSTRACT

A wafer transfer tool has a mounting end portion and a blade connected to and extending from the mounting end portion. The blade has a bottom exterior and a top exterior having a support configuration. The support configuration has a center point and steps having treads with inner edges. The treads are located in different levels in a direction of a thickness of the blade between the top exterior and the bottom exterior, wherein there are one or more of the treads at each level and wherein at least some of the inner edges have at least one of circular shapes or partially circular shapes.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. In a semiconductor manufacturing facility, systems are used to process semiconductor wafers and wafers are moved between these systems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows an illustration of wafers on transfer tools with blades, with one of the wafers being warped;

FIG. 2 shows an illustration of a wafer processing system, in accordance with some embodiments;

FIG. 3 shows an illustration of a top of a robot with a wafer transfer tool, in accordance with some embodiments;

FIG. 4 shows an illustration of a bottom of the wafer transfer tool, in accordance with some embodiments;

FIG. 5 shows an illustration of a top of the wafer transfer tool, in accordance with some embodiments;

FIG. 6 shows an illustration of a top of the wafer transfer tool with additional reference indicia;

FIG. 7 shows an illustration of a side of the wafer transfer tool, in accordance with some embodiments;

FIG. 8 shows an illustration of a side view of a wafer supported on a wafer transfer tool, in accordance with some embodiments; and

FIG. 9 shows a flow diagram illustrating a method of moving a wafer using a wafer transfer tool, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

In a semiconductor manufacturing facility, there are a number of highly specialized and automated systems for processing semiconductor wafers. These systems may be arranged in stations where one or more processes are performed. The semiconductor wafers are moved into, within, and between these stations. Some of this movement may be performed using carriers that hold a number of wafers. Carriers may be used to move wafers to and between stations or groups of stations. An example of a carrier may be a cassette having a plurality of slots for holding wafers in a horizontal orientation. These slots may be arranged vertically in one or more columns. At a station where processing is to occur, an automated robot may remove individual wafers from a carrier, such as a cassette, using a transfer blade held by an appendage of the robot. The robot moves the transfer blade such that the wafer remains horizontal on the transfer blade as it is moved from the carrier to processing apparatus at the station. In this manner, the wafer is maintained in its position on the transfer blade primarily through the operation of gravity.

During the transfer from the carrier to the processing apparatus, a wafer may, on occasion, shift out of position on the transfer blade and become “lost on the blade”. Such a shift in position may adversely affect the transfer of the wafer from the transfer blade to the processing apparatus. A number of factors may contribute to the shifting of a wafer. One such factor that may contribute to shifting of a wafer is warpage of the wafer. Warpage may cause the backside of a wafer to have less contact area with a top surface area of the transfer blade, thereby reducing frictional holding forces between the wafer and the transfer blade, which may be sufficient to allow shifting to occur.

Wafer warpage may occur when one or more layers are deposited on a substrate due to intrinsic stresses and the coefficient of thermal expansion (CTE) mismatch of the layers and the substrate.

Some types of wafers are more prone to warpage than other types of wafers. For example, gallium nitride (GaN) on Silicon (Si) wafers tend to be prone to warpage. A GaN layer may be deposited on a Si substrate by epitaxial crystal growth, such as by a metal-organic vapor phase epitaxy (MOVPE) deposition of c-plane GaN on a (111) Si substrate. The CTE of the GaN layer is significantly larger than the CTE of the Si, resulting in a mismatch that may be up to more than 50%. This large CTE mismatch, together with the lattice mismatch between the GaN layer and the Si substrate can lead to significant warpage of a GaN on a Si substrate.

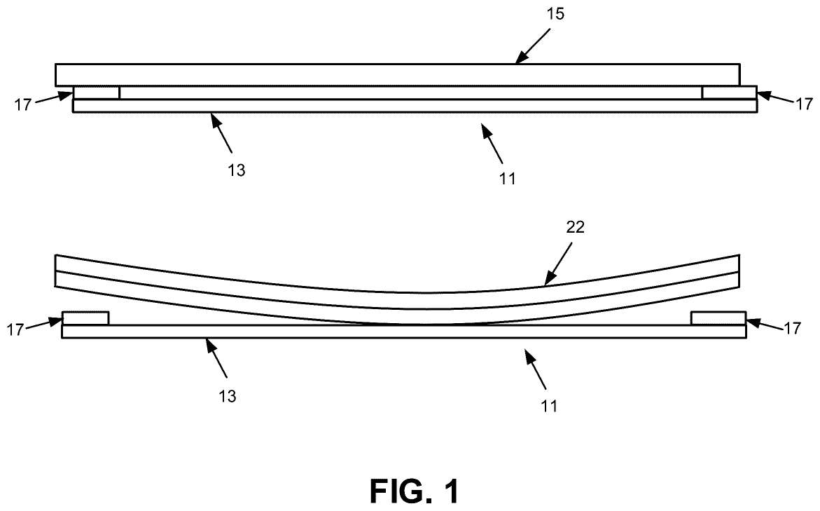

FIG. 1 shows a transfer tool 11 with a blade 13 supporting a complementary metal-oxide-semiconductor (CMOS) wafer 15 and another transfer tool 11 with a blade 13 supporting a wafer 22, which may be a GaN on Si wafer. The blade 13 has a pair of support structures 17, one located toward a mounting end of the transfer tool 11 and one located toward a free end of the blade 13. As shown, the CMOS wafer 15 is not warped and its outer portions are supported on the support structures 17. In contrast, the wafer 22 is warped and its outer portions are not supported on the support structures 17. Only a center portion of the wafer 22 is supported on a surface of the blade 13. As a result, the wafer 22 is not supported in a stable manner and is susceptible to shifting.

To mitigate shifting of the wafer on the transfer blade caused by wafer warpage or otherwise, one or more clamping devices may be used to hold the wafer on the transfer blade. In addition to, or in lieu of clamping device(s), one or more elastic pads may be mounted to the transfer blade to increase frictional holding forces between the wafer and the transfer blade. These shift-prevention features are useful for wafer transfer applications where the wafers are not overly fragile. According to some embodiments, a wafer transfer blade and method of using the same is provided for use with a wafer, regardless of whether the wafer is fragile, such as a GaN on Si wafer.

According to some embodiments, the wafer transfer tool includes a mounting end portion for connection to an arm assembly of a robot. A blade is connected to and extends from the mounting end portion. The blade includes a free end portion, a bottom exterior, and a top exterior having a support configuration. The support configuration has a center point and includes steps having treads with inner edges. The treads are located in different levels in the direction of a thickness of the blade between the top and bottom exteriors. There are one or more of the treads at each level. The treads have inner edges with circular shapes or partially circular shapes.

According to some embodiments, a combination may be formed that includes a wafer and the wafer transfer tool. The wafer has a bottom surface and a top surface. The top surface is concave, and the bottom surface is convex. The bottom surface is supported on the support configuration of the blade of the wafer transfer tool. The wafer has a first outermost portion that is closest to the free end portion of the blade and a second outermost portion that is closest to the mounting end portion of the transfer tool. The wafer has a center point that is offset from the center point of the support configuration of the blade. This offset of the wafer is toward the free end portion of the blade such that the first outermost portion of the wafer is higher than the second outermost portion of the wafer.

According to some embodiments, a robot may move the wafer transfer tool. The robot includes an arm assembly that is moved by one or more electric motors. The arm assembly includes a tool mount connected to the mounting end portion of the wafer transfer tool. The arm assembly includes a first articulated arm and a second articulated arm. The tool mount is pivotally connected to an outer end portion of the first articulated arm and to an outer end portion of the second articulated arm.

According to some embodiments, a method may include providing a wafer transfer tool having a blade with a free end portion, a bottom exterior, and a top exterior having a support configuration. The support configuration has a center point and includes steps having treads with inner edges. The inner edges are circular or partially circular. The blade is positioned below the wafer such that the support configuration supports a bottom surface of the wafer and such that a center of the wafer is offset from the center point of the support configuration, thereby tilting the wafer on the blade. The wafer transfer, with the wafer supported thereon, is then moved to another position.

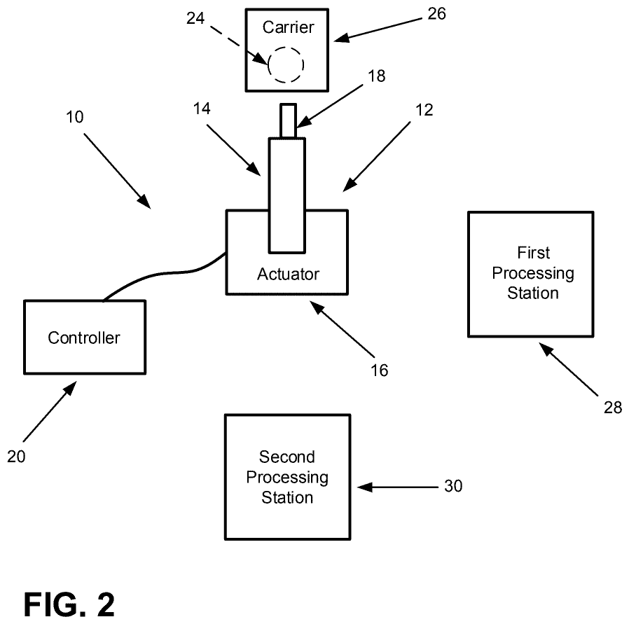

FIG. 2 is a schematic illustration of a wafer processing system in which a wafer transfer system 10 may operate, in accordance with some embodiments. The wafer transfer system 10 generally includes a robot 12 having an arm assembly 14 connected to an actuator assembly 16. An outer end of the arm assembly 14 is releasably fastened to a wafer transfer tool 18 and an inner end of the arm assembly 14 is connected to the actuator assembly 16. The wafer transfer tool 18 is configured to carry a semiconductor wafer 24. The wafer 24 may be a GaN on Si wafer, or another type of wafer. The actuator assembly 16 is configured to move the arm assembly 14 to move the wafer 24 from one location to another, such as from a carrier 26, such as a cassette, to a first processing station 28 and/or from the first processing station 28 to a second processing station 30, etc. The robot 12 is connected, either wirelessly or by hardwire connection, to a controller 20.

The controller 20 is configured to control the robot 12 to, inter alia, move a wafer 24 pursuant to a predetermined operating procedure. The controller 20 includes memory for storing computer executable code for performing the predetermined operating procedure, and one or more computer processors for executing the code. The predetermined operating procedure performed by the robot 12 may, by way of example, include removing the wafer 24 from the carrier 26 and transferring the wafer 24 into equipment in the first processing station 28, where a first process is performed on the wafer 24. This first process may, by way of example, be a chemical vapor deposition (CVD) process. After the CVD process is complete, such as may be determined from a signal received from the first processing station 28, the robot 12 may then remove the wafer 24 from the equipment in the first processing station 28 and transfer the wafer 24 to equipment in the second processing station 30 or elsewhere.

As a part of the above-described procedure, the controller 20 may control the robot 12 to move the wafer transfer tool 18 in a precise manner when removing the wafer 24 from the carrier 26 and equipment in the first processing station 28, the second processing station 30, and in other locations. More specifically, the robot 12 is moved to have the wafer 24 positioned on top of the wafer transfer tool 18 in a precise location, as will be described more fully below. Of course, the controller 20 may also control the robot 12 to move the wafer transfer tool 18 in a precise manner when inserting the wafer 24 into equipment in the first processing station 28, the second processing station 30, and in other locations, as well as otherwise moving the wafer 24.

In addition to being operatively connected to the robot 12, the controller 20 may also be operatively connected to equipment in the first processing station 28, the second processing station 30, and/or in other locations. Alternately or in addition, the controller 20 may be operatively connected to other controllers that control equipment in these locations and/or may be operatively connected to a main facility control system. With such connections, the control of the robot 12 may be coordinated with the control of the processes performed on the wafer 24 in the various locations to and from which the wafer 24 is moved.

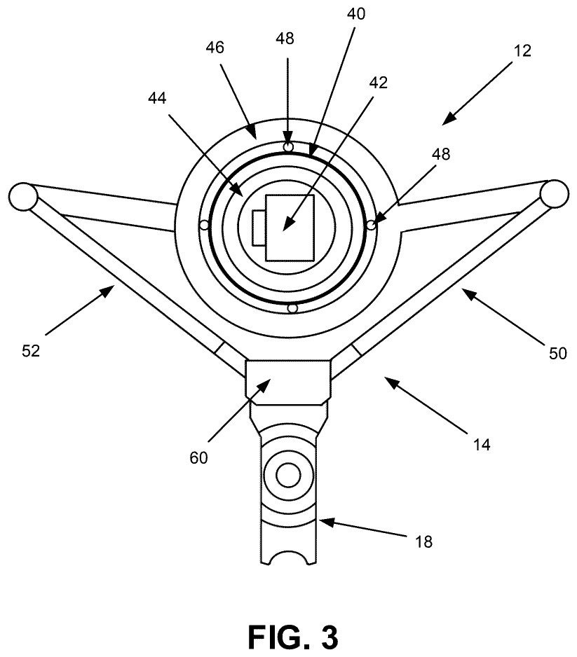

In some embodiments, the robot 12 may be a two arm-type of robot 12, an example of which is shown in FIG. 3. In these embodiments, the actuator assembly 16 may include a support 40 containing a pair of motors 42 configured to respectively rotate a pair of inner magnet rings 44 containing magnets. The motors 42 and inner magnet rings 44 may be arranged vertically, which is perpendicular to the drawing plane in FIG. 3. A pair of outer magnet rings 46 containing magnets may be movably mounted to an exterior of the support 40 by bearings 48. The outer magnet rings may also be arranged vertically.

An upper one of the inner magnet rings 44 is magnetically coupled to an upper one of the outer magnet rings 46, and a lower one of the inner magnet rings 44 is magnetically coupled to a lower one of the outer magnet rings 46. In this manner, when an upper one of the motors 42 rotates the upper one of the inner magnet rings 44, the upper one of the outer magnet rings 46 will rotate in the same direction at the same rotation rate. Similarly, when a lower one of the motors 42 rotates the lower one of the inner magnet rings 44, the lower one of the outer magnet rings 46 will rotate in the same direction at the same rotation rate.

The arm assembly 14 may include an articulated first arm 50 and an articulated second arm 52. Inner sections of the first and second arms 50, 52 may be secured to the outer magnet rings 46, respectively. For example, as shown in FIG. 3, the inner section of the first arm 50 may be secured to the upper one of the outer magnet rings 46, while the inner section of the second arm 52 may be secured to the lower one of the outer magnet rings 46. Outer sections of the first and second arms 50, 52 are connected by pivotable joints to the inner sections of the first and second arms 50, 52, respectively. End portions of the outer sections of the first and second arms 50, 52 are connected to pivots of a tool mount 60 so as to be pivotally movable relative to the tool mount 60. The tool mount 60 includes a fastener portion for releasable securement to a mounting end portion 62 of the wafer transfer tool 18.

The motors 42 of the actuator assembly 16 are controlled by the controller 20 to control the movement of the arm assembly 14. When the controller 20 instructs the motors 42 to rotate both of the outer magnet rings 46 (via the inner magnet rings 44) in the same direction with the same angular velocities, the arm assembly 14 also rotates in the same direction at the same angular velocity. Such angular movement of the arm assembly 14 may, by way of example, be used to move the wafer 24 from the carrier 26 to the first processing station 28.

When the controller 20 instructs the motors 42 to rotate the outer magnet rings 46 (e.g., via the inner magnet rings 44) in opposite directions with the same absolute angular velocity, then the arm assembly 14 does not rotate. Instead, the arm assembly 14 moves in a linear direction. The specific linear direction of the arm assembly 14, i.e., inward or outward, depends on the movement directions of the individual outer magnet rings 46 and the positions of the inner sections of the first and second arms 50, 52. For example, FIG. 3 shows the arm assembly 14 in a retracted position, with the inner sections of the first and second arms 50, 52 generally opposite each other. If the upper one of the outer magnet rings 46 is moved counterclockwise and the lower one of the outer magnetic rings 46 is moved clockwise, the inner sections of the first and second arms 50, 52 move towards each other, which causes the first and second arms 50, 52 to extend outwardly, thereby effecting outward linear movement of the arm assembly 14 to an extended position. If, when the arm assembly 14 is in the extended position, the upper one of the outer magnet rings 46 is then moved clockwise and the lower one of the outer magnetic rings 46 is moved counterclockwise, the inner sections of the first and second arms 50, 52 move away from each other, which causes the first and second arms 50, 52 to retract inwardly, thereby effecting inward linear movement of the arm assembly 14 to the retracted position.

The control of the motors 42 to move the arm assembly 14 ln a linear manner may be used to move wafers 22 into and out of holding places, such as slots in the carrier 26, and equipment, such as processing equipment in the first and second processing stations 28, 30.

As set forth above, end portions of the outer sections of the first and second arms 50, 52 are connected to pivots of the tool mount 60, which permit ends of the first and second arms 50, 52 to pivot when the first and second arms 50, 52 are linearly extended and retracted. The tool mount 60 may be releasably secured to the mounting end portion 62 of the wafer transfer tool 18.

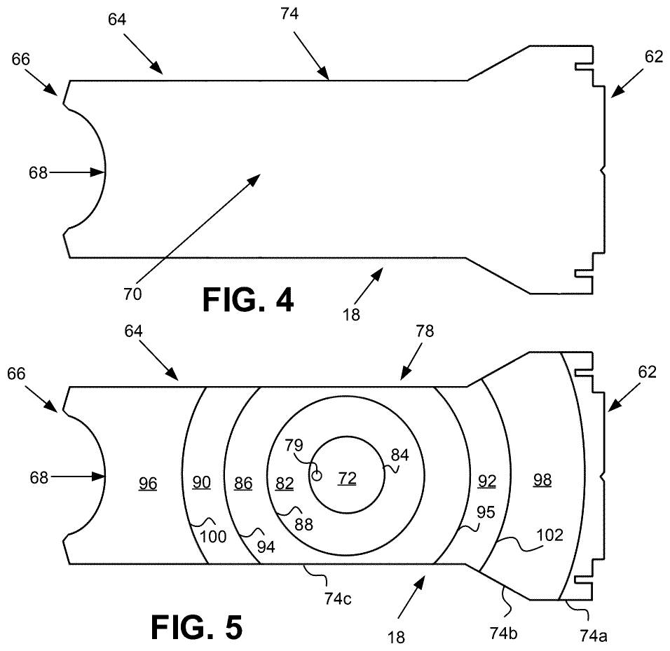

Referring now to FIGS. 4-7, the wafer transfer tool 18, in some embodiments, may comprise a unitary structure and may be formed from a ceramic, a metal, etc. An example of a ceramic that may be used includes sintered alumina ceramic. An example of a metal that may be used includes aluminum. In some embodiments, the wafer transfer tool 18 may have a multi-piece construction.

In addition to the mounting end portion 62, the wafer transfer tool 18 may include a blade 64 with a free end portion 66 having a curved interior edge 68. The wafer transfer tool 18 may have a planar bottom surface 70 that extends the length of the wafer transfer tool 18 between and including the mounting end portion 62 and the blade 64. The wafer transfer tool 18 may have a stepped top exterior that includes a plurality of top surfaces located at different depths in the direction of the thickness of the wafer transfer tool 18, with the top-most surface of the wafer transfer tool 18 being designated with the reference numeral 71 and the bottom-most surface being designated with the reference numeral 72. The top-most surface 71 may be located in the mounting end portion 62, while the bottom-most surface 72 may be located in a support configuration 78 described below.

The wafer transfer tool 18 may also have side surfaces 74 that extend the length of the wafer transfer tool 18 between and including the mounting end portion 62 and the blade 64. Each side surface 74 may have a first portion 74a that begins in the mounting end portion 62 and transitions to a second portion 74b that slopes inwardly to a third portion 74c that extends into the free end portion 66. In each side surface 74, the first portion 74a and the third portion 74c may be parallel. Accordingly, when viewed from above, as in FIG. 2, the wafer transfer tool 18 may have a tapered configuration, with the wafer transfer tool 18 being widest in the mounting end portion 62 and then tapering inward to a more narrow, generally rectangular configuration.

The blade 64 is configured to hold a wafer 24 during its horizontal movement from one location to another by the arm assembly 14 of the robot 12. The blade 64 may have a bottom portion that includes part of the bottom surface 70. The blade 64 may also include a top portion upon which a wafer 24 is supported during its horizontal movement from one location to another by the arm assembly 14 of the robot 12.

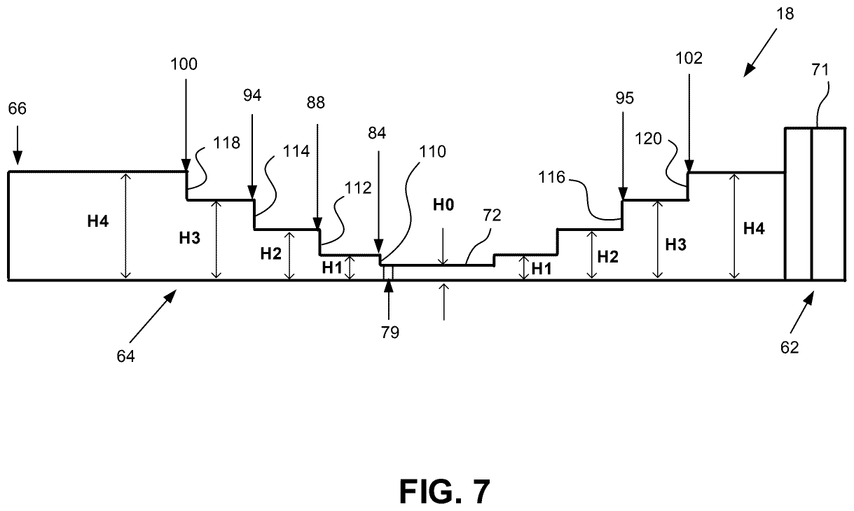

The top portion of the blade 64 may be stepped and have a support configuration 78 that include a series of surfaces located at different heights or levels in the direction of the thickness of the wafer transfer tool 18. These surfaces include the bottom-most surface 72 (also referred, at times, to as base surface 72), which is located in a center portion of the support configuration 78. The base surface 72 may be circular and may be located at a height H0 above the bottom surface 70, as shown in FIG. 7. A hole 79 may be formed in the blade 64 and may extend through the base surface 72 and the rest of the blade 64. As will be described more fully below, the hole 79 is aligned with a center 130 of the wafer 24 when the wafer 24 is in a transfer position on the blade 64.

A first surface 82 may surround and be located above the base surface 72. The first surface 82 may be annular and may be located at a height H1 above the bottom surface 70. The first surface 82 may be delimited by a first inner edge 84, which is circular, in some embodiments. A second surface 86 may surround and be located above the first surface 82. The second surface 86 may be mostly annular with portions cut-off at the side surfaces 74, in some embodiments. The second surface 86 may be located at a height H2 above the bottom surface 70. The second surface 86 may be delimited by a second inner edge 88, which may be circular, in some embodiments. Third surfaces 90, 92 may bracket and be located above the second surface 86. The third surfaces 90, 92 may be curved or arc-shaped and may be located at a height H3 above the bottom surface 70, in some embodiments. The third surfaces 90, 92 may be delimited by third inner edges 94, 95, which may be curved, or arc shaped, in some embodiments. Fourth surfaces 96, 98 may bracket the third surfaces 90, 92 and may be located above the third surfaces 90, 92. The fourth surfaces 96, 98 may be delimited by fourth inner edges 100, 102, respectively, which may be curved or arc-shaped, in some embodiments. The fourth surfaces 96, 98 may be located at a height H4 above the bottom surface 70. The height H4 is the maximum height or thickness of the blade 64, in some embodiments. In mathematical terms: H4>H3>H2>H1>H0. The height H0 may be greater than 1 mm to maintain the strength of the blade 64 and avoid fracture.

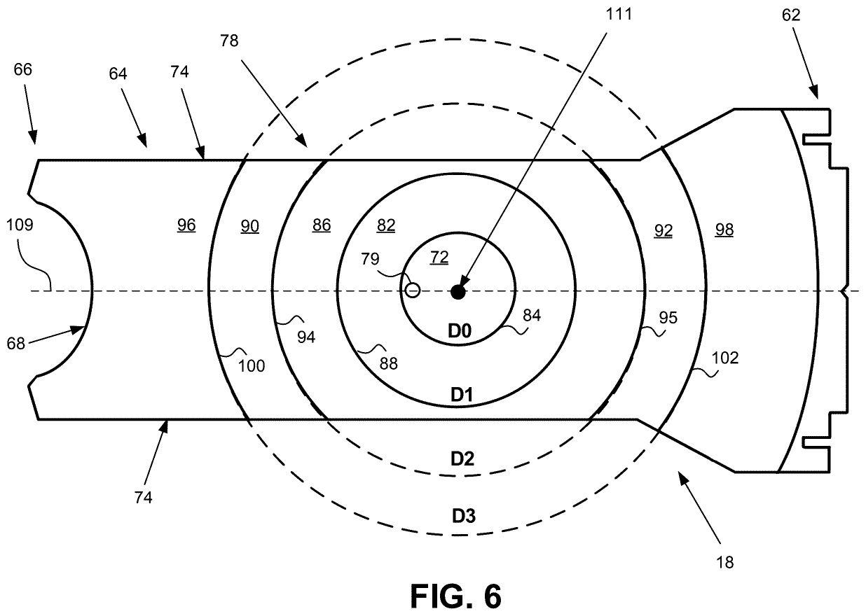

The base surface 72, the first surface 82, the second surface 86, and the third surfaces 90, 92 may all be circular or arc-shaped and may be disposed coaxial with each other. Similarly, the first inner edge 84, the second inner edge 88, the third inner edges 94, and the fourth inner edges 100, 102 may all be circular or arc-shaped and may be disposed coaxial with each other. More specifically, the first inner edge 84, the second inner edge 88, the third inner edges 94, 95, and the fourth inner edges 100, 102 may comprise all or portions of a plurality of concentric circles having diameters D0, D1, D2, D3, respectively, as shown in FIG. 6. The diameter W of a wafer 24 to be carried by the wafer transfer tool 18 is greater than D3 (which comprises the fourth inner edges 100, 102). In mathematical terms: W>D3>D2>D1>D0.

The circles with diameters D0, D1, D2, D3 share a center point 111 and, thus, the first inner edge 84, the second inner edge 88, the third inner edges 94, 95, and the fourth inner edges 100, 102 have the same center point 111. A longitudinal axis 109 of the blade 64 may extend through the center point 111, as shown in FIG. 6.

With particular reference to FIG. 7, the first surface 82 with the first inner edge 84 forms a first tread of a first step 110; the second surface 86 with the second inner edge 88 forms a second tread of a second step 112; the third surfaces 90, 92 with the third inner edges 94, 95 form third treads of third steps 114, 116; and the fourth surfaces 96, 98 with the fourth inner edges 100, 102 form fourth treads of fourth steps 118, 120. As such, the first tread of the first step 110 is located at the height (level) H1 of the blade 64; the second tread of the second step 112 is located at height (level) H2; the third treads of the third steps 114, 116 are located at height (level) H3; and the fourth treads of the fourth steps 118, 120 are located at height (level) H4. In this manner, at each level of the blade 64, there is one or more treads of one or more steps, wherein each tread is annular, mostly annular, or in the shape of an arc. Put another way, at each level of the blade 64, there is one or more treads of one or more steps, wherein each tread has an edge that is a circle or a part of a circle, i.e., a circular arc.

The support configuration 78 comprises the first step 110, the second step 112, the third steps 114, 116 and the fourth steps 118, 120. The center of the support configuration 78 is the center point 111.

The number and configuration of steps shown and described is for purposes of explanation and should not be considered limiting. The number of steps in the blade 64 and their configuration(s) may depend upon a number of factors, such as the typical warpage of a particular type of wafer that the blade 64 is intended to hold or whether the blade 64 is intended to hold a variety of different types of wafers having different typical warpages, etc. The blade 64 has at least two steps or two portions of a single step, wherein the two steps or two portions of the single step are disposed on opposite sides of the center point 111 along the longitudinal axis 109, so that a wafer is supported on the opposite sides. For example, in some embodiments (not shown), the blade 64 may only have the first step 110 or the second step 112. In these embodiments, the first step 110 and the second step 112 each have a continuous tread and a circular inner edge and, thus, each have two portions disposed on opposite sides of the center point 111 along the longitudinal axis 109 to support a wafer. In other embodiments (not shown), the blade 64 may only have the third steps 114, 116 or the fourth steps 118, 120, wherein each of these steps does not have a continuous tread or a circular inner edge. In these embodiments, there is two steps with one step (e.g. step 114 or step 118) disposed on one side of the center point 111 along the longitudinal axis 109 and another step (e.g. step 116 or step 120) disposed on the other side of the center point 111 along the longitudinal axis 109.

In some embodiments, the blade 64 may have different combinations of the first step 110, the second step 112, the third steps 114, 116, and/or the fourth steps 118, 120. For example, in some embodiments, the blade 64 may have at least two different levels in which each level has treads of two steps or two portions of a tread of a single step, wherein the treads of the two steps or two portions of the tread of the single step in each level are disposed on opposite sides of the center point 111 along the longitudinal axis 109. In one such embodiment, the blade 64 may have only the third steps 114, 116 and the fourth steps 118, 120. In another such embodiment, the blade 64 may only have the first step 110 and the second step 112. In still another such embodiment, the blade 64 may only have the first step 110 and the fourth steps 118, 120.

In some embodiments, the blade 64 may have steps in addition to those shown and described. Indeed, the blade 64 may have a large number of different levels in which each level has treads of two steps or two portions of a tread of a single step such that the treads approach forming a surface of a cap of a sphere or a part of such a surface, which when viewed from a cross section of the blade 64 taken along the longitudinal axis 109 would appear as an arc.

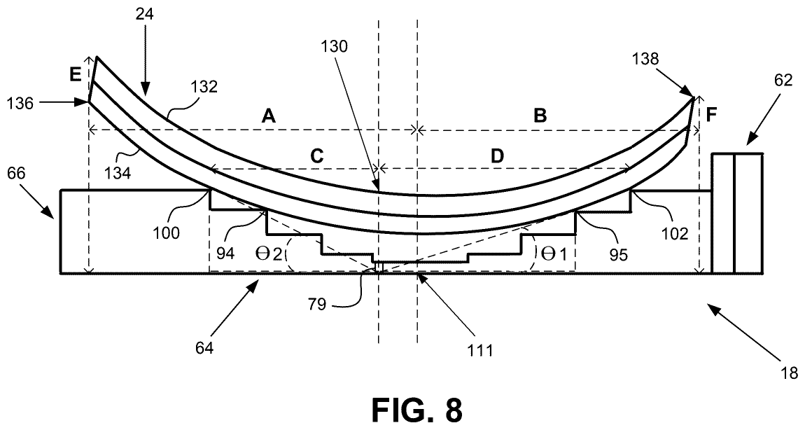

Referring now to FIG. 8, there is shown a wafer 24 disposed on the blade 64 of the wafer transfer tool 18. The wafer 24 is generally circular and has a center 130, a top surface 132, and a bottom surface 134. In the shown embodiment, the wafer 24 may be a GaN on Si wafer and is warped such that the top surface 132 is concave and the bottom surface is 134 is convex. The top surface 132 may be part of a top layer comprising GaN and the bottom surface 134 may be part of a bottom layer comprising Si.

When the wafer 24 is to be transported, the wafer 24 is disposed on the blade 64 in a transport position in which the bottom surface 134 of the wafer 24 is supported on the support configuration 78 or, more specifically, on treads of steps in two or more different levels of the blade 64. In addition, the center 130 of the wafer 24 is offset from the center point 111 of the support configuration 78 (inner edges of the steps). In the shown embodiment and other embodiments, the bottom surface 134 of the wafer 24 rests on the third inner edge 94 of the third tread of the third step 114 and on the fourth inner edge 100 of the fourth tread of the fourth step 120 on a first side of the center point 111, along the longitudinal axis 109, and rests on the third inner edge 95 of the third tread of the third step 116 and the fourth inner edge 102 of the fourth tread of the fourth step 120 on a second side of the center point 111 along the longitudinal axis 109. The above-described contact of the wafer 24 with the steps of the blade 64 provides a more distributed arrangement and increased number of support surfaces than the arrangement of the blade 13 shown in FIG. 1, thereby providing greater stability of the wafer 24 on the blade 64. Instead of only having its center supported like the blade 13, the wafer 24 has more outer portions supported. More specifically, two separate portions of the wafer 24 located outwardly from the center point 111 of the support configuration 78 are supported on each side of the center point 111 in the direction of the longitudinal axis 109.

As set forth above, when the wafer 24 is in the transport position, the center 130 of the wafer 24 is offset from the center point 111 of the support configuration 78 (inner edges of the steps). In the shown embodiment, the center 130 of the wafer 24 may be aligned over the hole 79, which is disposed proximate to the first inner edge 84 of the first step 110. With the wafer 24 so offset, the wafer 24 is positioned toward the free end portion 66 of the blade 64. A first outermost portion 136 of the wafer 24 is closest to the free end portion 66 of the blade 64 and a second outermost portion 138 of the wafer 24 is closest to the mounting end portion 62 of the wafer transfer tool 18. The distance between the center point 111 of the support configuration 78 and the first outermost portion 136 of the wafer 24 in the direction of the longitudinal axis 109 may be designated by the reference letter “A”, and the distance between the center point 111 of the support configuration 78 and the second outermost portion 138 of the wafer 24 may be designated by the reference letter “B”. Due to the shift of the wafer 24, the distance A is greater than the distance B, i.e., A>B. The size of the wafer 24 equals the sum of the distances A and B, in some embodiments.

The offset of the wafer 24 toward the free end portion 66 of the blade 64 tilts the wafer 24 to have the first outermost portion 136 of the wafer 24 be disposed higher than the second outermost portion 138 of the wafer 24. For instance, the first outermost portion 136 has a height E above the bottom surface 70 of the wafer transfer tool 18 and the second outermost portion 138 has a height F above the bottom surface 70, with the height E being greater than height F, i.e., E>F. The tilting of the wafer 24 helps prevent the wafer 24 from shifting when the wafer 24 is subjected to a centrifugal force, such as when the wafer 24 is moved in an arc, i.e., angularly. Such movement may occur when the arm assembly 14 of the robot 12 rotates to move the wafer transfer tool 18 and, thus, the wafer 24 from the carrier 26 to the first processing station 28.

When the wafer 24 is in the transport position, the distance between the center 130 of the wafer 24 (and the hole 79) and the fourth inner edge 100 of the fourth step 118 may be designated by reference letter “C”; and the distance between the center 130 of the wafer 24 (and the hole 79) and the fourth inner edge 102 of the fourth step 120 may be designated by the reference letter “D”. The distance C is less than the distance D, i.e., C<D.

When the wafer 24 is in the transport position, the distance between the center 130 of the wafer 24 (and the hole 79) at the bottom surface 70 and the fourth inner edge 100 of the fourth step 118 forms a hypotenuse of a first right triangle having angle Ø2. The opposite side is the height H4 and the adjacent side is the distance C. A hypotenuse of a second right triangle is formed by the length between the center 130 of the wafer 24 (and the hole 79) at the bottom surface 70 and the third inner edge 95. The second right triangle has an angle Ø1 and an opposite side that is the height H3 and an adjacent side that is equal to the distance between the center 130 of the wafer 24 (and the hole 79) at the bottom surface 70 and the third inner edge 95 of the third step 116. In some embodiments, angle Ø2 is greater than or equal to angle Ø1, which is greater than 0°. In mathematical terms: Ø2≥Ø1>0°. In some embodiments, the angle Ø2 is less than 5°, or sinØ2 is about equal to tanØ2.

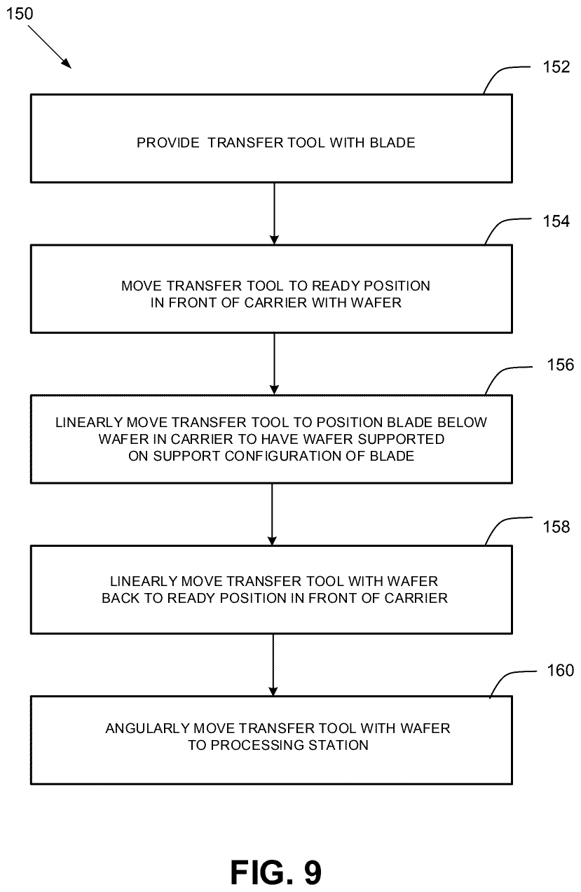

Referring now to FIG. 9, a method 150 of moving the wafer 24 may be performed in accordance with some embodiments. The method 150 may be performed, at least in part, using the robot 12 with the wafer transfer tool 18 connected thereto. The wafer 24 may be disposed in a slot in the carrier 26 in a horizontal position. In performing the method 150, the robot 12 may be controlled by the controller 20. At 152, the wafer transfer tool 18 may be provided for moving the wafer 24, such as by connecting the wafer transfer tool 18 to the tool mount 60 of the robot 12. At 154, the wafer transfer tool 18 is moved by the robot 12 to a first ready position in front of the carrier 26, proximate to the wafer 24. When the wafer transfer tool 18 is in the first ready position, the arm assembly 14 of the robot 12 may be in the retracted position. At 156, the robot 12 linearly moves the wafer transfer tool 18 outward to insert the blade 64 of the wafer transfer tool 18 underneath the wafer 24 to position the blade 64 such that the wafer 24 is in the transport position, i.e., the wafer 24 is supported on the support configuration 78 and the center 130 of the wafer 24 is offset from the center point 111 of the support configuration 78, thereby tilting the wafer 24 on the blade 64. When the wafer 24 is in the transport position on the blade 64, the wafer transfer tool 18 is in an engaged position and the arm assembly 14 may be in the extended position or a partially extended position.

To properly place the wafer transfer tool 18 in the engaged position, the controller 20 may control the outward motion of the arm assembly 14 using the hole 79 in the blade 64 and/or other feature to determine when the wafer 24 is in the transport position. For example, the controller 20 may stop the outward motion of the arm assembly 14 when the hole 79 is aligned with a marking on the bottom surface 134 of the wafer 24 at its center 130, such as by using a laser, thereby indicating that the wafer 24 is in the transport position. Alternately, the controller 20 may simply move the arm assembly 14 outward a specific predetermined distance, which automatically places the hole 79 in alignment with the center 130 of the wafer 24, which may be confirmed by a laser or other means.

At 158 (with the wafer 24 in the transport position on the blade 64), the robot 12 linearly moves the wafer transfer tool 18 inward, back to the first ready position. At 160, the robot 12 rotates the wafer transfer tool 18 (with the wafer 24) to a second ready position in front of the first processing station 28. During the movement of the wafer transfer tool 18 with the wafer 24, the wafer transfer tool 18 is maintained horizontal.

According to some embodiments, a wafer transfer tool is provided. The wafer transfer tool includes a mounting end portion and a blade connected to and extending from the mounting end portion. The blade has a bottom exterior and a top exterior having a support configuration. The support configuration has a center point and steps having treads with inner edges. The treads are located in different levels in a direction of a thickness of the blade between the top exterior and the bottom exterior. One or more of the treads are at each level and at least some of the inner edges have at least one of circular shapes or partially circular shapes.

According to some embodiments, an apparatus is provided. The apparatus includes a wafer and a wafer transfer tool. The wafer has a bottom surface and a top surface, wherein the top surface is concave and the bottom surface is convex. The wafer transfer tool includes a mounting end portion and a blade connected to and extending from the mounting end portion. The blade has a bottom exterior and a top exterior having a support configuration. The support configuration has a center point and steps having treads with inner edges. The treads are located in different levels in a direction of a thickness of the blade between the top exterior and the bottom exterior. The bottom surface of the wafer is supported on the support configuration of the blade of the wafer transfer tool. The wafer has a first outermost portion that is closest to a free end portion of the blade and a second outermost portion that is closest to the mounting end portion of the transfer tool.

According to some embodiments, a method is provided. The method includes providing a wafer transfer tool having a support configuration, the support configuration having a center point. The method includes positioning a blade of the wafer transfer tool below the wafer such that the support configuration supports a bottom surface of the wafer and such that a center of the wafer is offset from the center point of the support configuration, thereby tilting the wafer on the blade. The method includes moving the wafer transfer tool, upon which the wafer is supported, to another position.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A wafer transfer tool, comprising:
a mounting end portion; and
a blade connected to and extending from the mounting end portion, the blade comprising a bottom exterior and a top exterior having a support configuration, the support configuration having a center point and comprising steps having treads with inner edges, the treads being located in different levels in a direction of a thickness of the blade between the top exterior and the bottom exterior, wherein there are one or more of the treads at each level and wherein at least some of the inner edges have at least one of circular shapes or partially circular shapes.

2. The wafer transfer tool of claim 1, wherein at least one of the inner edges of the treads is circular.

3. The wafer transfer tool of claim 1, wherein a plurality of the inner edges of the treads is circular.

4. The wafer transfer tool of claim 1, wherein two of the treads are in a same level and have inner edges that are parts of a circle.

5. The wafer transfer tool of claim 1, wherein in two of the levels, there are two of the treads in each of the levels that have inner edges that are each part of a circle, and wherein in two other of the levels, there is one of the treads in each of the levels that has an inner edge that is a circle.

6. The wafer transfer tool of claim 1, wherein the bottom exterior of the blade has a planar bottom surface.

7. The wafer transfer tool of claim 1, wherein the inner edges of the treads are coaxial with a center corresponding to the center point of the support configuration; and
wherein the blade has a longitudinal axis that extends through the center point of the support configuration.

8. The wafer transfer tool of claim 1, wherein the blade has at least two different levels in which each of the levels has at least two of the treads or two portions of a single one of the treads disposed on opposite sides of the center point of the support configuration along a longitudinal axis of the blade.

9. An apparatus, comprising:
a wafer having a bottom surface and a top surface, wherein the top surface is concave and the bottom surface is convex; and
a wafer transfer tool, comprising:
a mounting end portion; and
a blade connected to and extending from the mounting end portion, the blade comprising a bottom exterior and a top exterior having a support configuration, the support configuration having a center point and comprising steps having treads with inner edges, the treads being located in different levels in a direction of a thickness of the blade between the top exterior and the bottom exterior, wherein:
the bottom surface of the wafer is supported on the support configuration of the blade of the wafer transfer tool; and
the wafer has a first outermost portion that is closest to a free end portion of the blade and a second outermost portion that is closest to the mounting end portion of the wafer transfer tool.

10. The apparatus of claim 9, wherein the bottom surface of the wafer is supported on two of the treads or two portions of a single one of the treads.

11. The apparatus of claim 9, wherein the wafer has a center point that is offset from the center point of the support configuration of the blade.

12. The apparatus of claim 11, wherein the offset of the wafer is toward the free end portion of the blade such that the first outermost portion of the wafer is higher than the second outermost portion of the wafer.

13. The apparatus of claim 9, wherein the blade has a longitudinal axis that extends through the center point of the support configuration.

14. The apparatus of claim 9, wherein the wafer comprises a layer of gallium nitride disposed on a silicon substrate.

15. The apparatus of claim 9, comprising a robot for moving the wafer transfer tool, the robot comprising an arm assembly movable by one or more electric motors, the arm assembly including a tool mount connected to the mounting end portion of the wafer transfer tool.

16. The apparatus of claim 15, wherein the arm assembly comprises a first articulated arm and a second articulated arm, and wherein the tool mount is pivotally connected to an outer end portion of the first articulated arm and to an outer end portion of the second articulated arm.

17. The apparatus of claim 16, wherein the robot comprises:
a support within which the one or more electric motors are disposed;
one or more inner magnetic rings connected to the one or more electric motors to be moved by the one or more electric motors;
one or more outer magnetic rings rotatably mounted to the support and magnetically coupled to the inner magnetic rings, wherein inner end portions of the first and second articulated arms are connected to the one or more outer magnetic rings; and
a controller to control operation of the one or more electric motors to move the arm assembly to move the tool mount and, thus, the wafer transfer tool, linearly and angularly.

18. A method of moving a wafer, comprising:
providing a wafer transfer tool having a support configuration, the support configuration having a center point;
positioning a blade of the wafer transfer tool below the wafer such that the support configuration supports a bottom surface of the wafer and such that a center of the wafer is offset from the center point of the support configuration, thereby tilting the wafer on the blade; and
moving the wafer transfer tool, upon which the wafer is supported, to another position.

19. The method of claim 18, wherein the wafer is warped to have a concave top surface and a convex bottom surface, and wherein tilting the wafer comprises moving a first outermost portion of the wafer higher than a second outermost portion of the wafer, the first outermost portion of the wafer being proximate to a free end portion of the blade and the second outermost portion of the wafer being distal to the free end portion of the blade.

20. The method of claim 18, wherein the moving the wafer transfer tool to another position comprises moving the wafer transfer tool linearly and angularly.
